(19) United States
(12) Patent Application Publication
(10) Pub. No.: US 2023/0341450 A1
(43) Pub. Date: Oct. 26, 2023

(54) CAPACITANCE DETECTION CIRCUIT

(71) Applicant: Chung Dam SONG, Hwaseong-si (KR)

(72) Inventor: Chung Dam SONG, Hwaseong-si (KR)

(21) Appl. No.: 17/793,170

(22) PCT Filed: Jan. 13, 2021
(86) PCT No.: PCT/KR2021/000438

§ 371 Date: Jul. 15, 2022

(30) Foreign Application Priority Data
Jan. 23, 2020 (KR) 10-2020-0009295

(51) Int. Cl. G01R 27/26; H03K 17/955

(52) U.S. Cl. CPC G01R 27/2605; H03K 17/955

(57) ABSTRACT

The present disclosure relates to a capacitance detection circuit using a sample and hold circuit to simplify the circuit configuration and improve temperature characteristics. The capacitance detection circuit includes a constant current part, a sawtooth waveform generator for generating a sawtooth waveform voltage, a sensing part, a peak value detector for detecting a peak value of a sawtooth waveform voltage in a non-signal period and a peak value of a sawtooth waveform voltage in a sensing period input from the sawtooth waveform generator, a constant current automatic control comparator for providing a negative feedback loop for generating a reference voltage when there is no signal to the constant current part, a sample and hold part, an alternative current (AC) amplifier, a zero volt clamp detector and a voltage comparator for outputting a detection signal.

### TECHNICAL FIELD

The present disclosure relates to a capacitance detection circuit, and more particularly, to a capacitance detection circuit using a sample and hold circuit to simplify the circuit configuration and improve variations in device characteristics and temperature characteristics.

### DESCRIPTION OF THE RELATED ART

Recently, many sensors have been developed that may detect an object using a change in capacitance or measure a pressure, a water level, or an amount of a substance. As a method for detecting a change in capacitance, a method using a bridge circuit in the related art, a method using a charge/discharge time of a capacitor, a method using an oscillation circuit, and the like are used.

As shown in FIG. 6, the electrostatic sensor circuit registered as Patent No. 10-1879285 by the present applicant previously applied by making two detection circuits using the charging and discharging of the capacitors C1 and C2, and one of them is used for the reference voltage and the detection sensitivity is improved by peak detection of the sensing signal. Referring to FIG. 6, the electrostatic sensor circuit 10 in the related art includes a C-V converter 11, a sensor 12, two peak detectors 13-1 and 13-2, a DC amplifier 14, a low-pass filter 15 (LPF), and a comparator 16, and the C-V converter 11 generates a sawtooth waveform voltage by charging and discharging the first capacitor C1 and the second capacitor C2 according to clock signals from two constant current sources, respectively. Although the related art has the effect of overcoming the effect of noise and improving the detection sensitivity, the circuit configuration is rather complicated.

### DISCLOSURE OF THE INVENTION

### Technical Goals

The technical aspect to be solved by the present disclosure is to provide a capacitance detection circuit which simplifies the circuit configuration by using a sample hold circuit, reduces the number of parts, and improves device characteristics deviation and temperature characteristics because operations of a plurality of identical circuits are used together by one circuit.

### Technical Solutions

The present example embodiment discloses a capacitance detection circuit in which variations in device characteristics and temperature characteristics are improved by using one circuit for operations of a plurality of identical circuits.

The capacitance detection circuit disclosed in the present disclosure includes a constant current part for supplying a charging constant current for generating a sawtooth waveform voltage, a sawtooth waveform generator for generating a sawtooth waveform voltage by charging a capacitor by the constant current part and discharging it by a clock, a sensing part (sensor part) that changes the capacitor capacitance of the sawtooth waveform generator when the capacitance of an object is sensed by a sensor, a peak value detector for detecting a peak value of a sawtooth waveform voltage in a non-signal period and a peak value of a sawtooth waveform voltage in a sensing period input from the sawtooth waveform generator, a constant current automatic control comparator for providing a negative feedback loop for generating a reference voltage when there is no signal to the constant current part, a sample and hold part, which is disposed between the peak value detector and the constant current automatic control comparator, for connecting the negative feedback loop during a non-signal period, blocking the negative feedback loop during a sensing period, and then providing a sampled and held voltage to the constant current automatic control comparator, an alternative current (AC) amplifier for AC amplifying the output of the peak value detector, a zero volt clamp detector for detecting a peak value of an AC signal by synchronously detecting the output of the AC amplifier, and a voltage comparator for outputting a detection signal by comparing the output of the zero volt clamp detector with a detection reference voltage.

The capacitance detection circuit may further include a low pass filter for low pass filtering the output of the zero volt clamp detector.

The constant current part includes an offset control switch that cuts off the connection between the current controller and the constant current source during a non-signal period according to the constant current source, the current controller and the first sample and hold clock CP1, and then connects the current controller to the constant current source during the sensing period and adds current to the constant current part so that the sawtooth waveform voltage reaches the non-signal voltage in the absence of a detection object during the sensing period.

The sensing part includes a sensor switch that connects the correction capacitor to the sawtooth waveform generator during the non-signal period according to the correction capacitor and the first sample and hold clock CP1, and then connects the sensor to the sawtooth waveform generator during the sensing period so that the total capacity of the sawtooth waveform generator may be changed by the sensor.

The sample and hold part includes a first operational amplifier that functions as a temperature compensation and buffer, a sample and hold switch that receives a second sample and hold clock, the sample and hold capacitor that holds the sampled value during the sensing period in which the sample and hold switch is turned off after sampling the output of the peak value detector during the non-signal period in which the sample and hold switch is turned on, and a second operational amplifier that transmits the signal transmitted from the sample and hold switch to the constant current automatic control comparator during the non-signal period and transmits the held signal of the sample and hold capacitor to the constant current automatic control comparator during the sensing period.

The sensor is an element that detects the capacitance of the object when the object approaches, and may be an electrode having a predetermined area or a capacitor including two electrodes with an insulator interposed therebetween.

### Effects

According to the example embodiment, since operations of a plurality of identical circuits are used together by one circuit, the circuit configuration used is simplified and the number of parts is reduced, and variations in element characteristics and temperature characteristics are improved. In addition, according to present example implementation, the signal sensed by the sample and hold method is converted into an AC signal by switching the detected voltage and the non-signal voltage, respectively, so that AC amplification is possible, and thus there is a strong advantage in hum noise. In addition, in the example embodiment, the sensing sensitivity may not be decreased by adjusting the offset so that the sensing voltage approaches the non-signal voltage.

### BRIEF DESCRIPTION OF THE DRAWINGS

FIG. 1 is a block diagram showing a capacitance detection circuit according to an example embodiment of the present disclosure.

FIG. 2 is a detailed circuit diagram of the sample and hold circuit shown in FIG. 1.

FIG. 3 is an example of a clock timing diagram for sample and hold according to an example embodiment of the present disclosure.

FIG. 4 is an example of a sawtooth waveform and a peak detection signal waveform according to an example embodiment of the present disclosure.

FIG. 5 is an example of a waveform for explaining the operation of the capacitance detection circuit according to the example embodiment of the present disclosure.

FIG. 6 is an example showing an electrostatic sensor circuit in the related art.

### DETAILED DESCRIPTION FOR CARRYING OUT THE INVENTION

The present disclosure and the technical goals achieved by the practice of the present disclosure will become clearer by the preferred example embodiments of the present disclosure described below. The following example embodiments are merely exemplified to illustrate the present disclosure, and are not intended to limit the scope of the present disclosure.

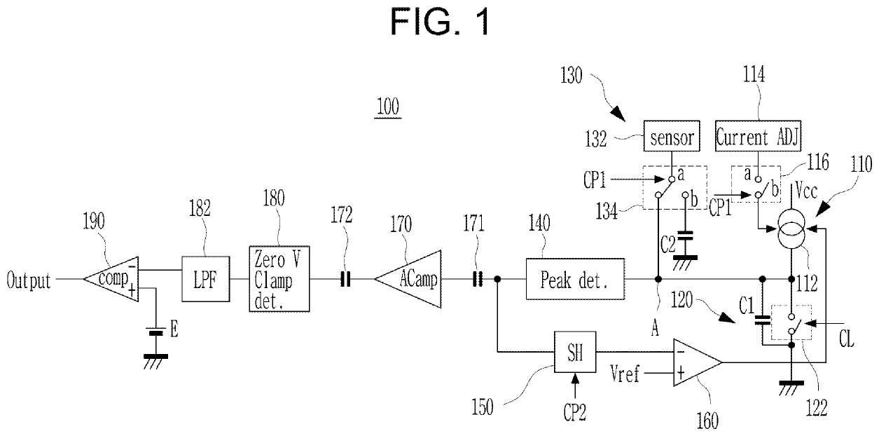

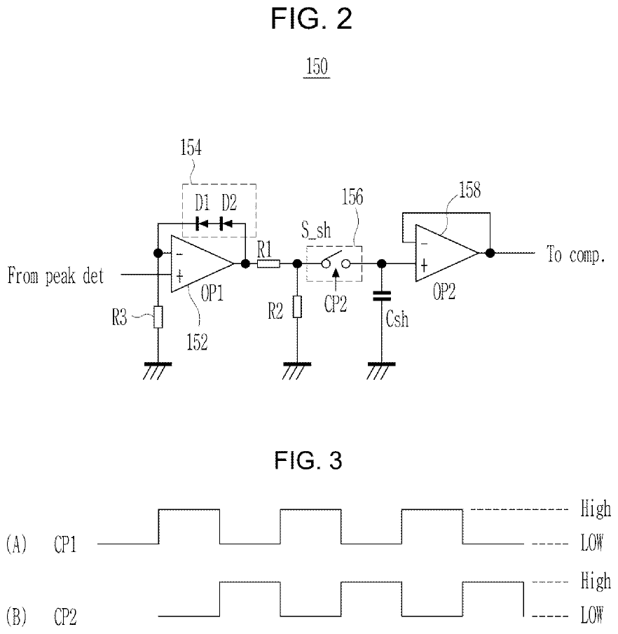

FIG. 1 is a block diagram showing a capacitance detection circuit according to an example embodiment of the present disclosure, FIG. 2 is a detailed circuit diagram of the sample and hold circuit shown in FIG. 1, and FIG. 3 is an example of timing diagram of a clock for sample and hold according to an example embodiment of the present disclosure.

As shown in FIG. 1, the capacitance detection circuit 100 according to an example embodiment of the present disclosure consists of a constant current source 112, a current controller 114, an offset control switch 116, a first capacitor C1, a clock switch 122, a sensor 132, a sensor switch 134, a correction capacitor C2, an AC amplifier 170, a zero volt clamp detector 180, a low pass filter 182, a voltage comparator 190, and coupling capacitors 171 and 172. The sensor 132 is an electrode having a predetermined area or a capacitor including two electrodes with an insulating layer interposed therebetween. Unexplained reference numeral 110 in FIG. 1 denotes a constant current part composed of a constant current source 112, a current controller 114, and an offset control switch 116, and reference numeral 120 denotes the sawtooth waveform generator composed of a first capacitor C1 and a clock switch 122, and reference numeral 130 denotes a sensing part (sensor part) composed of the sensor 132, the sensor switch 134, and the correction capacitor C2.

First, clocks used in the example embodiment of the present disclosure include a system clock CL for controlling the clock switch 122 to generate a sawtooth waveform voltage, the first sample and hold clock CP1 that becomes high during the non-signal period and low during the sensing period, and the second sample and hold clock CP2 that is out of phase with the first sample and hold clock CP1 to become low in the non-signal period and high in the sensing period. As shown as (A) in FIG. 3, the first sample and hold clock CP1 becomes high during the non-signal period so that the offset control switch 116 is connected to ‘b’ to turn off the current controller 114, and the sensor switch 134 is connected to ‘b’ so that the correction capacitor C2 is connected in parallel to the first capacitor C1. In addition, as shown as (A) in FIG. 3 it becomes low during the sensing period so that the offset control switch 116 is connected to ‘a’ to connect the current controller 114 to the constant current source 112, and the sensor switch 134 is connected to ‘a’ so that the sensor 132 is connected in parallel to the first capacitor C1.

As shown as (B) in FIG. 3, the second sample and hold clock CP2 becomes low during the non-signal period and becomes high during the sensing period so that the sample and hold part 150 connects the negative feedback loop during the non-signal period and blocks the negative feedback loop during the sensing period, and then provides the sampled and held voltage to the constant current automatic control comparator 160.

In an example embodiment of the present disclosure, the system clock CL may be approximately 125 KHz, and the sample and hold clocks CP1 and CP2 may be 3.9 KHz.

In addition, in the example embodiment of the present disclosure, a negative feedback loop is implemented so that the constant current becomes a reference when making a non-signal voltage in a constant current circuit that generates a sawtooth waveform voltage for sensing, and if the negative feedback loop is maintained even during the sensing period, the sensing signal follows the non-signal voltage by the negative feedback loop of the constant current circuit, making it difficult to distinguish the difference between the non-signal output and the detected output. Therefore, in the example embodiment of the present disclosure, the negative feedback loop is formed during the non-signal period, the negative feedback loop is cut off during the sensing period, and the negative feedback voltage at that time is sampled and held to maintain the same voltage. In this way, the current generating the sawtooth waveform voltage becomes constant, and the wave peak value of the sawtooth waveform voltage in the sensing period and the non-signal period is different, so that it may be detected.

On the other hand, because the constant current generated by the negative feedback loop is made by configuring the negative feedback loop so that the wave peak value of the sawtooth waveform voltage is the same as Vref (reference voltage), a stable constant current may be obtained. However, since this constant current is made in a state in which the sensor 132 is not connected, it is necessary to correct the capacitance to some extent in order to approach the capacitance generated by the sensor itself. In the example embodiment of the present disclosure, the correction capacitor C2 is connected to the first capacitor C1 through the sensor switch 134 during the non-signal period to perform correction as will be described later. Accordingly, when the capacitance of the circuit elements connected to the periphery is neglected, the total capacitance at the time of non-signal may be regarded as approximately C1+C2.

Referring to FIG. 1, the constant current part 110 is composed of a constant current source 112, a current controller 114, and an offset control switch 116, and supplies a charging constant current for generating a sawtooth waveform to the sawtooth waveform generator 120.

In this case, in reality, when the sensing circuit and the sensing part (sensor part) are mounted on a case or the like, the voltage during the non-signal period and the voltage when there is no object during the sensing period do not necessarily match. It arises from the subtle difference between the total capacity during non-signal and the total capacity during sensing. In order to improve this, it is necessary to adjust the offset so that the sending voltage reaches the non-signal voltage in the absence of a detection object during the sensing period.

In the example embodiment of the present disclosure, the offset control switch 116 cuts off the current control part 114 (connected to ‘b’ to turn it off) during the non-signal period according to the first sample and hold clock CP1, and during the sensing period, the current control part 114 is connected to the constant current source 112 and current is added to the constant current part 110 so that the sawtooth waveform voltage reaches the non-signal voltage in the absence of a detection object during the sensing period. That is, in the example embodiment of the present disclosure, the offset is adjusted so that the sensing voltage approaches the non-signal voltage so that the sensing sensitivity does not decrease.

The sawtooth waveform generator 120 is composed of a first capacitor C1 and a clock switch 122 to charge the first capacitor C1 by the charging constant current i of the constant current part 110, and a sawtooth waveform voltage is generated by discharging the first capacitor CP1 by the system clock CL.

In general, when a sawtooth waveform is generated to detect the capacitance, if (i) is a constant current, the sawtooth waveform voltage may be obtained as in Equation 1 below.

$$[ Equation 1 ]$$

$$V = \frac{1}{C}$$

Here, T is determined by the time of the system clock, which is preferably generated by dividing the crystal oscillation for precision.

In the example embodiment of the present disclosure, when the detection capacity of the sensing part 130 changes while i and t are constant, the peak value of the sawtooth waveform voltage changes due to the change in C to sense an object.

The sensing part 130 includes a sensor 132, a sensor switch 134, and a correction capacitor C2, and the total capacity C of the sensing part 120 is changed when an object is sensed by the sensor 132. The sensor switch 134 connects the correction capacitor C2 to the first capacitor C1 in parallel in the non-signal period according to the first sample and hold clock CP1, and connects the sensor 132 to the first capacitor C1 during the sensing period so that the total capacitance C of the sawtooth waveform generator 120 may be changed by the sensor 132.

Therefore, the sawtooth waveform generator 120 generates a sensing voltage close to the non-signal voltage when the object is not detected by the sensor 132 during the sensing period, and when the object is sensed by the sensing part 130, the total capacity C increases, the sensing voltage decreases, and the object is detected by the voltage difference.

The peak value detector 140 detects the sawtooth waveform voltage peak value of the non-signal period input from the sawtooth waveform generator 120 and the sawtooth waveform voltage peak value of the detection time.

As shown in FIG. 2, the sample and hold part 150 is composed of a first operational amplifier 152, a sample and hold switch 156, a capacitor Csh for sample and holding, a second operational amplifier 158, a resistors R1, R2, R3 and diodes D1, D2, and maintains a negative feedback loop by connecting the output of the peak value detector 140 to the constant current automatic control comparator 160 in the non-signal period according to the second sample and hold clock CP2, and transfers the sampled and held output of the peak value detector 140 to the constant current automatic control comparator 160 after blocking the negative feedback loop during the detection period. The constant current automatic control comparator 160 compares the output of the sample and hold part 150 with the reference voltage Vref and feeds it back to the constant current part 110.

Referring to FIG. 2, the first operational amplifier 152 has a temperature compensation and buffer function, the second operational amplifier 158 is for sample and hold, and the sample and hold capacitor Csh is a sample and hold switch 156, and the sample and hold capacitor Csh samples the output of the peak value detector 140 during a non-signal period in which the sample and hold switch 156 is on, and then holds sampled value during a sensing period in which the sample and hold switch 156 is turned off.

The temperature compensation resistor R3 is connected to the −input terminal of the first operational amplifier 152, and the temperature compensation diodes 154; D1, D2 are connected to the output terminal and the −input terminal. The output of the peak value detector 140 is input to the +input terminal of the first operational amplifier 152.

The voltage divider resistors R1 and R2 for sample and hold are connected to the output terminal of the first operational amplifier 152, and the sample and hold switch 156 is connected between the voltage divider resistors R1 and R2 and the sample and hold capacitor Csh.

The second operational amplifier 158 transmits the signal transmitted from the sample and hold switch 156 to the constant current automatic control comparator 160 during the non-signal period, and transmits the signal held by the sample and hold capacitor Csh to the constant current automatic control comparator 160 during the sensing period.

Referring back to FIG. 1, the AC amplifier 170 AC amplifies the output of the peak detector 140, and the zero volt clamp detector 180 synchronously detects the output of the AC amplifier 170 to detect the peak value of the AC signal. At this time, the output of the sensing voltage is clamped to zero voltage so that the voltage increases when there is a sensing signal. The coupling capacitors 171 and 172 are for transmitting an AC signal. As described above, in the example embodiment of the present disclosure, since a noise component of a low frequency (0 to several hundred Hz) is removed by directly converting direct current to alternating current (ex. 3.9 kHz) by applying the sample and hold, the signal processing strong against hum noise becomes possible. In addition, although general DC amplification affects the characteristics even if there is a slight error, AC amplification is easy to configure and may improve stability.

The low pass filter 182 low-pass filters the output of the zero-voltage clamp detector 180, and the voltage comparator 190 compares the low-pass-filtered output of the zero volt clamp detector 180 with the detection reference voltage E to output the detection signal.

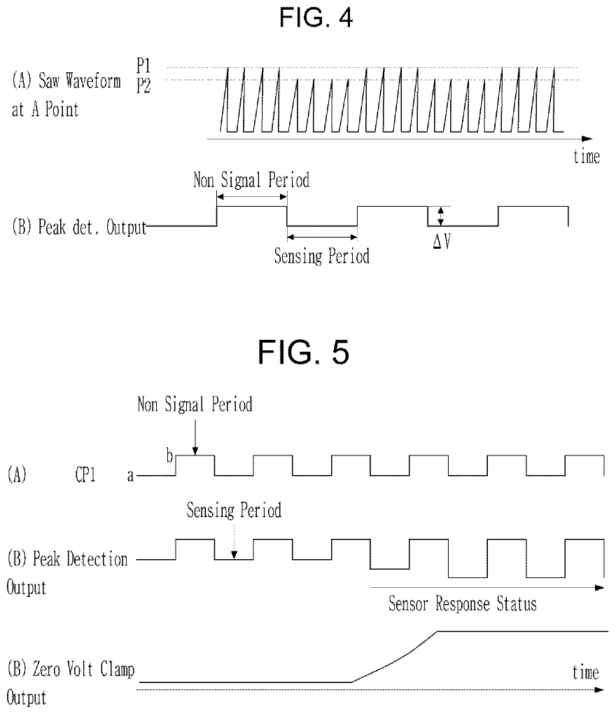

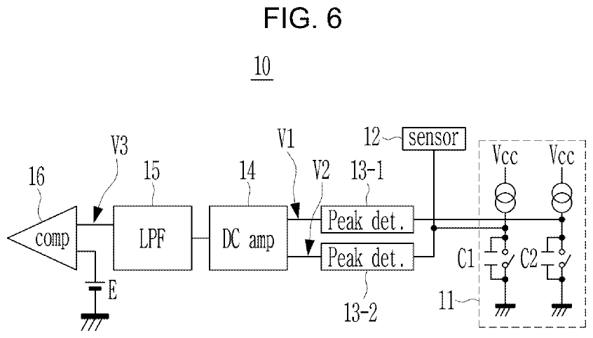

FIG. 4 is an example of a sawtooth waveform and a peak detection signal waveform according to the example embodiment of the present disclosure, and FIG. 5 is an example of a waveform for explaining the operation of the capacitance detection circuit according to the example embodiment of the present disclosure.

Referring to FIG. 4, (A) is a waveform diagram showing the sawtooth waveform voltage at point A of FIG. 1, where P1 is the peak value of the sawtooth waveform in a non-signal period, and P2 is the peak value of the sawtooth waveform in the sensing period. (b) is an output waveform of the peak value detector 140, and an object may be detected by the difference (ΔV) between the voltage during the non-signal period and the voltage during the sensing period.

Referring to FIG. 5, (A) is a timing diagram of the first sample and hold clock CP1, (B) is an output voltage waveform diagram of the peak value detector 140, (C) is the output voltage waveform diagram of a zero volt clamp detector 180. The non-signal period and the sensing period are repeated by the first sample and hold clock CP1, and when an object is detected during the sensing period and the sensing part 130 starts to react, it may be seen that the sensing period voltage of the peak value detector 140 gradually decreases and the output voltage of the zero volt clamp detector 180 gradually increases.

In the above, the present disclosure has been described with reference to one example embodiment shown in the drawings, but it will be understood by those skilled in the art that various modifications and equivalent other example embodiments are possible therefrom.

1. A capacitance detection circuit comprising:
a constant current part for supplying a charging constant current for generating a sawtooth waveform voltage;
a sawtooth waveform generator including a capacitor and a clock, generating a sawtooth waveform voltage by charging a capacitor by the constant current part and discharging it by a clock;
a sensing part that changes the capacitor capacitance of the sawtooth waveform generator when the capacitance of an object is sensed by a sensor;
a peak value detector for detecting a peak value of a sawtooth waveform voltage in a non-signal period and a peak value of a sawtooth waveform voltage in a sensing period input from the sawtooth waveform generator;
a constant current automatic control comparator for providing a negative feedback loop for generating a reference voltage when there is no signal to the constant current part;
a sample and hold part, which is disposed between the peak value detector and the constant current automatic control comparator, for connecting the negative feedback loop during a non-signal period, blocking the negative feedback loop during a sensing period, and then providing a sampled and held voltage to the constant current automatic control comparator;
an alternating current (AC) amplifier for AC amplifying an output of the peak value detector;
a zero volt clamp detector for detecting a peak value of an AC signal by synchronously detecting an output of the AC amplifier; and
a voltage comparator for outputting a detection signal by comparing an output of the zero volt clamp detector with a detection reference voltage.

2. The capacitance detection circuit according to claim 1, further include a low pass filter for low pass filtering an output of the zero volt clamp detector.

3. The capacitance detection circuit according to claim 1,
wherein the constant current part includes an offset control switch that cuts off a connection between the current controller and a constant current source during a non-signal period according to a constant current source, a current controller and a first sample and hold clock CP1, and then connects a current controller to the constant current source during a sensing period and adds current to a constant current part so that a sawtooth waveform voltage reaches a non-signal voltage in an absence of a detection object during a sensing period.

4. The capacitance detection circuit according to claim 1,
wherein the sensing part includes a sensor switch that connects the correction capacitor to a sawtooth waveform generator during a non-signal period according to a sensor, a correction capacitor and a first sample and hold clock CP1, and then connects a sensor to a sawtooth waveform generator during a sensing period so that a total capacity of a sawtooth waveform generator may be changed by a sensor.

5. The capacitance detection circuit according to claim 1,
wherein the sample and hold part includes a first operational amplifier that functions as a temperature compensation and buffer, a sample and hold switch that receives a second sample and hold clock, the sample and hold capacitor that holds the sampled value during the sensing period in which the sample and hold switch is turned off after sampling an output of the peak value detector during the non-signal period in which the sample and hold switch is turned on, and a second operational amplifier that transmits a signal transmitted from the sample and hold switch to a constant current automatic control comparator during the non-signal period and transmits a held signal of the sample and hold capacitor to a constant current automatic control comparator during the sensing period.
